(19) United States
(12) Patent Application Publication
(10) Pub. No.: US 2026/0280274 A1
(43) Pub. Date: Sep. 17, 2026

(54) PYROTECHNIC BATTERY DISCONNECT SYSTEM AND ASSOCIATED OPERATING METHOD

(71) Applicant: Isabellenhuette Heusler GmbH & Co. KG, Dillenburg (DE)

(72) Inventors: Michael POLLMANN, Dillenburg (DE); Felix LEBEAU, Herborn (DE)

(21) Appl. No.: 19/471,078

(22) PCT Filed: Apr. 12, 2024
(86) PCT No.: PCT/EP2024/059999

§ 371 Date: Sep. 30, 2025

(30) Foreign Application Priority Data
May 9, 2023 (DE) 102023112113.8

(51) Int. Cl. H02H 7/18; B60L 3/04; G01R 31/3842; G01R 31/74; G07C 5/08; H01H 85/04

(52) U.S. Cl. CPC H02H 7/18; B60L 3/04; G01R 31/3842; G01R 31/74; G07C 5/0808; B60L 2240/547; B60L 2240/549; H01H 85/04

(57) ABSTRACT

The invention relates to a pyrotechnic battery disconnect system (1) having an electric high-voltage battery (2) with a low side at low-voltage potential (LV) and a high side at high-voltage potential (HV), a pyro fuse (4) for electrically disconnecting the high-voltage battery (2), wherein the pyro fuse (4) is connected in series with the high-voltage battery (2) and is arranged on the high side of the high-voltage battery (2) such that the pyro fuse (4) is at the high-voltage potential (HV), and having a control circuit (7) with a trip output for tripping the pyro fuse (4), wherein the pyro fuse (3) cuts off the high-voltage battery (2) upon tripping. According to the invention, the control circuit (7) is likewise arranged on the high side of the high-voltage battery (2) and is at the high-voltage potential (HV) in order, when the pyro fuse (4) trips, to avoid a brief short circuit between the high-voltage potential (HV) of the pyro

### TECHNICAL FIELD OF THE INVENTION

The invention relates to a pyrotechnic battery disconnect system, in particular for a motor vehicle electrical system of a battery-electric car or a hybrid car. Furthermore, the invention comprises an associated operating method.

### BACKGROUND OF THE INVENTION

In modern electric cars (BEV: battery electric vehicle) and hybrid cars (PHEV: plug-in hybrid electric vehicle), high-voltage batteries with a battery voltage of more than 60 volts are used to supply power to the electric drive motors. For example, high-voltage batteries with a battery voltage of 400 volts or 800 volts are already in use. Due to the high battery voltage of such high-voltage batteries, it is important to electrically protect the high-voltage battery in order to quickly and reliably disconnect it from the vehicle electrical system in the event of an accident or a fault-related overcurrent. So-called pyrotechnic fuses are used for this purpose. These contain an electrically triggered ignition capsule that quickly and reliably interrupts the circuit (“busbar”) by means of a small explosion. Such pyrotechnic fuses are marketed, for example, by the German company Miba AG under the product name “Miba POWERfuse®”. The pyrotechnic fuses are usually located on the high side of the high-voltage battery in a high-voltage section, while the pyrofuse is controlled by a control circuit located in a low-voltage section.

The problem here is that when the pyrotechnic fuse is triggered, a short circuit occurs briefly between the pyrotechnic fuse in the high-voltage section and the control circuit in the low-voltage section.

### DESCRIPTION OF THE INVENTION

The invention is therefore based on the task of improving the known pyrotechnic battery disconnect systems in such a way that even when the pyrotechnic fuse is triggered, no brief short circuit occurs between the high-voltage section and the low-voltage section. Furthermore, the invention is based on the task of specifying a corresponding operating method for such a pyrotechnic battery disconnect system.

This task is solved by a pyrotechnic battery disconnect system according to the invention or by a corresponding operating method according to the independent claims.

The pyrotechnic battery disconnect system according to the invention initially comprises a high-voltage battery with a high side and a low side in accordance with the prior art. In the preferred embodiment of the invention, the high-voltage battery is rechargeable, but it is also possible in principle to implement the invention with a non-rechargeable battery. It should also be mentioned that the high-voltage battery preferably supplies a battery voltage of more than 60 V, 200 V, 400 V, 600 V or 800 V. However, the invention is not limited to the above-mentioned exemplary values with regard to the battery voltage.

In addition, in accordance with the prior art described at the outset, the pyrotechnic battery disconnect system according to the invention comprises a pyrotechnic fuse in order to be able to quickly and reliably disconnect the high-voltage battery in the event of an accident or a fault-related overcurrent. The pyrotechnic fuse is connected in series with the high-voltage battery and arranged on the high side of the high-voltage battery so that the pyrotechnic fuse is at the high-voltage potential. Such pyrotechnic fuses are known from the prior art and therefore do not need to be described in detail. For example, such pyrotechnic fuses can be obtained from the German company Miba AG under the product name “Miba POWERfuse@”. However, the invention is not limited to this type of pyrotechnic fuse, but can also be implemented with other types of pyrotechnic fuses.

Furthermore, in accordance with the prior art, the pyrotechnic battery disconnect system according to the invention comprises a control circuit to trigger the pyrotechnic fuse in the event of an accident or a fault-related overcurrent, whereby the pyrotechnic fuse then disconnects the high-voltage battery when triggered by the control circuit.

The invention is distinguished from the prior art in that the control circuit is also located on the high side of the battery and is at high voltage potential in order to prevent a brief short circuit between the high voltage potential of the pyrotechnic fuse on the one hand and the low voltage potential on the other when the pyrotechnic fuse is triggered. In the pyrotechnic battery disconnect system according to the invention, both the pyrotechnic fuse and the control circuit are therefore at the high-voltage potential, so that the short circuits that occur briefly between the pyrotechnic fuse on the one hand and the control circuit on the other when the pyrotechnic fuse is triggered by the control circuit no longer have any harmful effects, as is the case with the prior art described at the beginning.

It should be noted here that the low-voltage potential can be the ground potential (“chassis ground”) of the power supply. However, within the scope of the invention, it is also possible for the low-voltage potential to be a higher potential that is above the ground potential (“chassis ground”) of the power supply. The only decisive factor in the context of the invention is that the low-voltage potential is significantly lower than the high-voltage potential.

In addition, the pyrotechnic battery disconnect system according to the invention preferably has an electrical energy storage device to provide the electrical energy required to trigger the pyrotechnic fuse. For example, this electrical energy storage device may be a capacitor (e.g. double-layer capacitor, supercapacitor). However, the invention is not limited to capacitors with regard to the type of electrical energy storage device, but can in principle also be implemented with other types of energy storage devices that can supply a sufficiently large trigger current quickly enough to trigger the pyrotechnic fuse.

Furthermore, the pyrotechnic battery disconnect system according to the invention preferably comprises a controllable switching element in order to connect the electrical energy storage device (e.g. capacitor) for triggering the pyrotechnic fuse to the pyrotechnic fuse, wherein the switching element can be controlled via a trigger output of the control circuit. In the preferred embodiment of the invention, the switching element is a power transistor (e.g. MOSFET: metal oxide semiconductor field-effect transistor), but the invention can also be implemented with other types of switching elements.

To trigger the pyrotechnic fuse, the control circuit then controls the switching element in such a way that the energy storage device (e.g. capacitor) is connected to the pyrotechnic fuse for a specific trigger duration, whereby a specific trigger current then flows through the pyrotechnic fuse during the trigger duration in order to trigger it. The trigger current and the trigger duration are therefore sufficiently large together to trigger the pyrotechnic fuse.

It should be noted that the trigger current and the trigger duration must be appropriately dimensioned in order to trigger the pyrotechnic fuse. For example, a very high trigger current with an extremely short trigger duration may not be sufficient to trigger the pyrotechnic fuse. Furthermore, a very long trigger duration with a correspondingly low trigger current may also not be suitable for triggering the pyrotechnic fuse. In the preferred embodiment of the invention, the trigger current is at least 500 mA, 1 A, or 2 A, while the trigger duration is at least 500 μs, 1 ms, 2 ms, or 4 ms. However, the suitable values for the trigger current and the trigger duration depend on the data of the pyrotechnic fuse and may therefore vary.

It should also be mentioned that the control circuit is preferably designed as an integrated circuit (IC). However, within the scope of the invention, there is also the alternative possibility that the control circuit is a discrete circuit or that its functions are distributed among various components.

In the preferred embodiment of the pyrotechnic battery disconnect system according to the invention, a current limiter is arranged between the electrical energy storage device (e.g. capacitor) and the pyrotechnic fuse in order to limit the trigger current to a maximum value and thereby keep the trigger current as constant as possible during the trigger duration. This makes it possible to design the energy storage device smaller, i.e., due to the current limitation, a lower capacity of the energy storage device is sufficient. For example, the maximum value of the trigger current specified by the current limiter can be a maximum of 5 A, 3 A, or 2 A. This current limitation means that the trigger current fluctuates less during the trigger duration. Without current limitation, the trigger current decreases exponentially during the trigger duration in accordance with the discharge curve of a capacitor and thus fluctuates greatly. With the current limitation according to the invention, the fluctuations in the trigger current during the trigger duration between the switching edges can be reduced to less than 50%, 30%, 20%, 10% or even less than 5%. As already mentioned above, this offers the advantage that an energy storage device with a lower capacity is sufficient. In the preferred embodiment of the invention, the current limiter can be implemented in the circuit by means of a constant current source, but other designs for the current limiter are also possible within the scope of the invention.

It should also be mentioned that a transformer may be provided for charging the electrical energy storage device (e.g. capacitor), which receives a supply voltage (e.g. +12V) on the input side and provides a higher charging voltage (e.g. +48V) on the output side for charging the energy storage device.

It has already been mentioned above that the pyrotechnic fuse should be triggered in the event of an overcurrent, i.e., if an excessively high battery current flows during operation due to a fault. To measure the battery current, a first current sensor is therefore preferably provided, which measures the battery current, whereby the control circuit queries the first current sensor via a first measurement input. The control circuit then triggers the pyrotechnic fuse when an evaluation of the measured battery current indicates an overcurrent condition, in particular when the measured battery current exceeds a predetermined maximum value. When detecting an overcurrent condition by the control circuit, the duration of the current increase can be taken into account in addition to the level of the battery current.

In the preferred embodiment of the invention, the first current sensor has a low-resistance current measuring resistor (“shunt”) connected in series with the high-voltage battery, so that the battery current also flows through the first low-resistance current measuring resistor. The control circuit then measures the voltage drop across the first low-resistance current measuring resistor via the first measuring input, whereby the measured voltage drop across the first low-resistance current measuring resistor is then, in accordance with Ohm's law, a measure of the battery current flowing through the first low-resistance current measuring resistor. The first low-resistance current measuring resistor preferably has a small resistance value of less than 100 mΩ, 50 mΩ, 10 mΩ, 5 mΩ, 1 mΩ, 500 μΩ, 250 μΩ, or 100 μΩ.

It should also be mentioned that the first current sensor is preferably located on the high side of the high-voltage battery. This is advantageous because there is then no potential difference to bridge between the control circuit on the high-voltage potential on the one hand and the first current sensor on the high-voltage potential on the other. However, within the scope of the invention, it is also possible for the first current sensor to be located on the low side of the high-voltage battery.

The pyrotechnic battery disconnect system according to the invention preferably also allows the pyrotechnic fuse to be tested, whereby the pyrotechnic fuse is not triggered during the test. For this purpose, the control circuit may have a test output that allows the pyrotechnic fuse to be tested. During a test procedure, the control circuit then drives a test current through the pyrotechnic fuse, whereby the test current is so small that it is not sufficient to trigger the pyrotechnic fuse. To measure the test current during a test procedure, the pyrotechnic battery disconnect system preferably has a second current sensor, which is queried via a second measuring input of the control circuit. The control circuit can then detect a fault in the pyrotechnic fuse by evaluating the test current flowing during a test procedure.

It should be noted that the test output of the control circuit can be a digital output. It should also be noted that the test current is preferably less than 1 A, 500 mA, 250 mA, or 100 mA so that the pyrotechnic fuse is not triggered by the test current. However, the magnitude of the test current depends on the data of the respective pyrotechnic fuse and can therefore vary according to the respective pyrotechnic fuse. The only decisive factor is that the test current is low enough that the pyrotechnic fuse is not triggered by the test current.

The second current sensor for measuring the test current can function in the same way as the first current sensor for measuring the battery current. For this purpose, the second current sensor can have a second low-resistance current measuring resistor, which is arranged between the test output of the control circuit and the pyrotechnic fuse and through which the test current flows during the test process. The control circuit then measures the voltage drop across the second low-resistance current measuring resistor via the second measuring input, which, according to Ohm's law, provides a measure of the test current. For example, the second low-resistance current measuring resistor may have a resistance value of less than 100 mΩ, 50 mΩ, 10 mΩ, 5 mΩ, 1 mΩ, 500 μΩ, 250 μΩ, or 100 μΩ.

It is also possible to connect a series resistor in series with the second low-resistance current measuring resistor to limit the test current. This limitation of the test current also prevents the test current from causing the pyrotechnic fuse to trip unintentionally. When using such a series resistor, it is also possible to use the series resistor for current measurement by measuring the voltage drop across the series resistor. In this case, a low-resistance current measuring resistor for measuring the test current is not required, i.e., the series resistor can be used for current measurement and does not have to be low-resistance.

It has already been mentioned above that the pyrotechnic fuse should be triggered in the event of an accident (crash), among other things. For this purpose, the control circuit preferably has an interface connection that enables the reception of a crash signal triggered by a crash sensor. For example, the crash sensor can be an airbag sensor that sends the crash signal to a battery management system (BMS), which then triggers the charging circuit for the pyrotechnic fuse. Alternatively, the control circuit of the pyrotechnic battery disconnect system according to the invention may also include the functions of the battery management system (BMS), so that the battery management system is integrated into the control circuit. The control circuit can then receive the crash signal via the interface connection.

A potential separation element is preferably connected to the interface connection of the control circuit in order to decouple the control circuit, which is at high voltage potential, from the crash signal from the low voltage section.

It should be noted that the interface connection of the control circuit preferably not only enables the reception of a crash signal, but also the reception and retransmission of a diagnostic signal. The diagnostic signal preferably differs from the crash signal so that the control circuit can distinguish the incoming diagnostic signal from the crash signal and the pyrotechnic fuse does not trigger when the diagnostic signal is received. For example, the diagnostic signal may have a different signal level or signal shape than the crash signal to enable differentiation. In the preferred embodiment of the invention, the diagnostic signal has a significantly lower signal level than the crash signal.

It has already been mentioned above that the interface connection preferably also enables the reception and retransmission of a diagnostic signal. Thus, the diagnostic signal for a diagnosis is first transmitted to the control circuit, and the control circuit then responds with a retransmission of the diagnostic signal if it is functioning correctly. To enable such a return transmission of the diagnostic signal, the potential separation element mentioned above preferably enables bidirectional data transmission, namely data transmission to the control circuit in a first transmission channel and data transmission back from the control circuit in a second transmission channel. The two transmission channels of the potential separation element are preferably combined towards the control circuit and connected together to the interface connection of the control circuit. Externally, however, the two transmission channels of the potential separation element preferably run separately from each other. It should also be mentioned that data transmission in the two transmission channels can be either analog or digital.

In addition, the control circuit preferably has a charge control output for controlling the charging process for charging the electrical energy storage device (e.g. capacitor). The charge control output of the control circuit preferably controls a controllable second switching element (e.g. power transistor, MOSFET), wherein the second switching element selectively connects the electrical energy storage device (e.g. capacitor) to the transformer or disconnects it from the transformer. In addition, the control circuit preferably has a third measuring input which is connected to the energy storage device in order to measure the charging voltage at the energy storage device. By measuring the charging voltage and controlling the second switching element accordingly, the control circuit can then control the charging process.

In the preferred embodiment of the invention, the control circuit preferably has an analog-to-digital converter at each of its measuring inputs for battery current, test current, and charging current, as well as at the interface connection, in order to enable internal digital data processing. However, there is also the alternative possibility of providing only one analog-to-digital converter, which, however, has several measuring channels.

It has already been mentioned above that the control circuit triggers the pyrotechnic fuse in the event of an accident (crash) or overcurrent. In the preferred embodiment, the control circuit triggers the pyrotechnic fuse in both cases. However, the invention also claims protection for a pyrotechnic battery disconnect system in which the pyrotechnic fuse is triggered in only one of the two cases or additionally in another case.

It should also be mentioned that the above-mentioned parts and components are preferably integrated in a common assembly, which can be arranged in a common housing. For example, this common assembly can contain the following parts:
The first current sensor for measuring the battery current,
the control circuit for triggering the pyrotechnic fuse,
the energy storage device for providing the energy to trigger the pyrotechnic fuse,
the second current sensor for measuring the test current,
the transformer for providing the charging voltage for the energy storage device,
the potential separation element,
the first switching element for connecting the energy storage device to the pyrotechnic fuse,
the second switching element for connecting the energy storage device to the transformer,
the diode,
the series resistor for limiting the test current,
the current limiter for limiting the trigger current, and/or
a microcontroller for communicating with the control circuit.

The pyrotechnic battery disconnect system according to the invention, which can be used, for example, in a motor vehicle electrical system, has been described above. However, the invention also claims protection for a complete motor vehicle electrical system with such a pyrotechnic battery disconnect system according to the invention.

Furthermore, it should be noted that the invention is not limited to use in a motor vehicle electrical system. Rather, the pyrotechnic battery disconnect system according to the invention can also be used in stationary systems.

Furthermore, within the scope of the invention, there is also the possibility that the pyrotechnic battery disconnect system according to the invention could be used in other types of vehicles that have an electrical vehicle electrical system, such as rail vehicles (e.g. locomotives, railcars, freight cars, passenger cars), aircraft (e.g. airplanes, helicopters), spacecraft (e.g. rockets, space gliders, space stations), or watercraft (e.g. ships, boats, submarines).

It should also be mentioned that the invention also claims protection for a complete motor vehicle with such a motor vehicle electrical system with the pyrotechnic battery disconnect system according to the invention. The motor vehicle may be, for example, a battery electric vehicle (BEV) or a plug-in hybrid electric vehicle (PHEV).

Finally, the invention also claims protection for a corresponding operating method, whereby the individual steps of the operating method according to the invention are already apparent from the above description of the pyrotechnic battery disconnect system according to the invention, so that a separate description of the operating method according to the invention can be dispensed with.

Other advantageous further developments of the invention are indicated in the dependent claims or are explained in more detail below together with the description of the preferred embodiment of the invention with reference to the figures.

### BRIEF DESCRIPTION OF THE DRAWINGS

FIG. 1 shows a schematic representation of a circuit diagram of a pyrotechnic battery disconnect system according to the invention.

FIG. 2 shows a flow chart illustrating the operating method of the pyrotechnic battery disconnect system according to the invention.

### DETAILED DESCRIPTION OF THE DRAWINGS

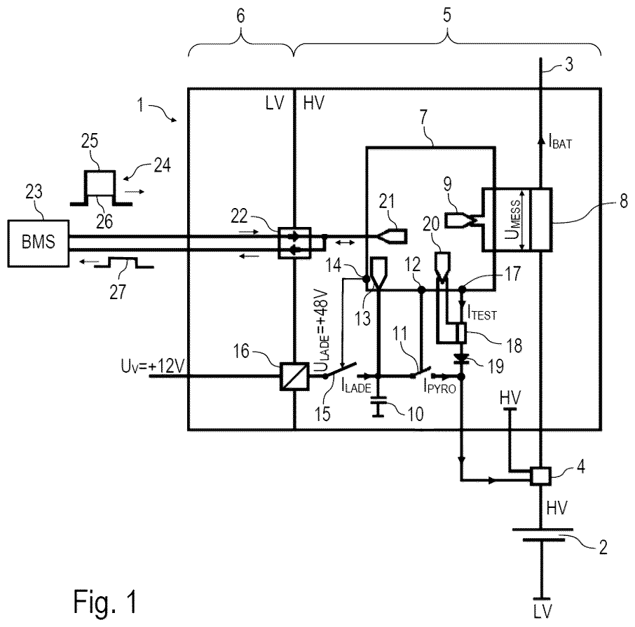

The circuit diagram of a pyrotechnic battery disconnect system 1 according to the invention shown in FIG. 1 is now described below.

The pyrotechnic battery disconnect system shown is used to disconnect a high-voltage battery 2 in the vehicle electrical system of a battery electric vehicle (BEV), whereby only the high-voltage battery 1 and a vehicle electrical system cable 3 are shown for the sake of simplicity.

A pyrotechnic fuse 4 is arranged in the vehicle electrical system cable 3 on the high side of the high-voltage battery 2 and connected in series with the high-voltage battery 2. The pyrotechnic fuse 4 enables the high-voltage battery 2 to be quickly and reliably disconnected from the vehicle electrical system in the event of an accident (crash) or a fault-related overcurrent.

The pyrotechnic battery disconnect system 1 initially consists of a high-voltage section 5 at high-voltage potential HV (High Voltage) and a low-voltage section 6 at low-voltage potential LV (Low Voltage). It should be noted here that the low-voltage potential LV can be the ground potential (“chassis ground”) of the power supply. However, within the scope of the invention, it is also possible that the low-voltage potential LV is a higher potential that is above the ground potential (“chassis ground”) of the power supply. The only decisive factor within the scope of the invention is that the low-voltage potential LV is significantly lower than the high-voltage potential HV.

In the high-voltage section 5 of the pyrotechnic battery disconnect system 1, there is a control circuit 7, which is designed as an integrated circuit and controls the operation of the pyrotechnic battery disconnect system 1.

During operation of the motor vehicle, a battery current I_{BAT} flows through the vehicle electrical system cable 3, which can be measured by a low-resistance current measuring resistor 8, wherein the control circuit 7 has a measuring input 9 for measuring a measuring voltage U_{MESS} dropping across the low-resistance current measuring resistor 8. The measuring voltage U_{MESS} then forms a measure of the battery current I_{BAT} flowing through the current measuring resistor 8 in accordance with Ohm's law. It should be noted here that the measuring input 9 of the control circuit 7 has an analog/digital converter which converts the analog measured value of the measuring voltage U_{MESS} into a corresponding digital value and enables digital signal processing in the control circuit 7. In this way, the control circuit 7 can detect an overcurrent, which then enables the pyrotechnic fuse 4 to be triggered, as will be described in more detail below.

In addition, the pyrotechnic battery disconnect system 1 has a capacitor 10 to provide the electrical energy required to trigger the pyrotechnic fuse 4. The capacitor 10 is connected to the pyrotechnic fuse 4 via a MOSFET 11, whereby the MOSFET 11 is controlled via a trigger output 12 of the control circuit 7. To trigger the pyrotechnic fuse 4, the control circuit 7 controls the MOSFET 11 in such a way that the MOSFET 11 switches through and thus connects the capacitor 10 to the pyrotechnic fuse 4. The capacitor 10 then discharges via the switched-on MOSFET 11 into the pyrotechnic fuse 4, whereby a trigger current I_{PYRO} flows that is sufficiently large and lasts long enough to trigger the pyrotechnic fuse 4. For example, the trigger current I_{PYRO} can be 2 A.

The control circuit 7 also has the task of controlling the charging process of the capacitor 10. For this purpose, the control circuit 7 has a measuring input 13 with an analog/digital converter to measure the charging voltage U_{LADE} at the capacitor 10. If an insufficient charging voltage U_{LADE} is measured, the control circuit 7 can then control a switching element 15 via a charge control output 14 in order to connect the capacitor 10 to a transformer 16. The input side of the transformer 16 is supplied by a smaller supply voltage U_{V}=+12V.

In addition to controlling the charging process of capacitor 10 as described above, the measurement of the charging voltage U_{LADE} can also be used for diagnostic purposes. For example, the control circuit 7 can determine by measuring the charging voltage U_{LADE} whether there is sufficient electrical energy stored in the capacitor 10 to trigger the pyrotechnic fuse 4.

In addition, the control circuit 7 also enables a test of the pyrotechnic fuse 4. For this purpose, the control circuit 7 can drive a small test current I_{TEST} through the pyrotechnic fuse 4, whereby the test current I_{TEST} is so small that it does not trigger the pyrotechnic fuse 4. For this purpose, the control circuit 7 has a digital test output 17 at which the test current I_{TEST} is output. The test output 17 is connected to the pyrotechnic fuse 4 via a low-resistance current measuring resistor 18 and a diode 19. The low-resistance current measuring resistor 18 enables the test current I_{TEST} by the control circuit 7. For this purpose, the control circuit 7 has a further measuring input 20 with an analog/digital converter to measure the electrical voltage drop across the low-resistance current measuring resistor 18, which, according to Ohm's law is a measure of the test current I_{TEST}. In this way, the control circuit 7 can detect a possible malfunction of the pyrotechnic fuse 4.

In addition, the control circuit 7 has an interface connection 21 with an analog/digital converter. The interface connection 21 of the control circuit 7 is connected via a potential separation element 22 to a battery management system 23 (BMS), which receives a crash signal from a crash sensor in the event of an accident. This enables communication between the battery management system 23 and the control circuit 7. The battery management system 23 transmits a signal 24 to the control circuit 7, which evaluates the signal 24. If the signal level 25 is high, the control circuit 7 detects an accident (crash) and then triggers the pyrotechnic fuse 4. If the signal level 26 of signal 24 is low, however, the control circuit 7 recognizes a diagnostic signal and then responds with a corresponding diagnostic signal 27, which is transmitted back from the control circuit 7 to the battery management system 23. In this way, the battery management system 23 can detect whether the control circuit 7 is working correctly, since the diagnostic signal 27 is not transmitted back if the control circuit 7 malfunctions.

Alternatively, the invention also provides for the possibility of integrating the battery management system 23 (BMS) into the control circuit 7.

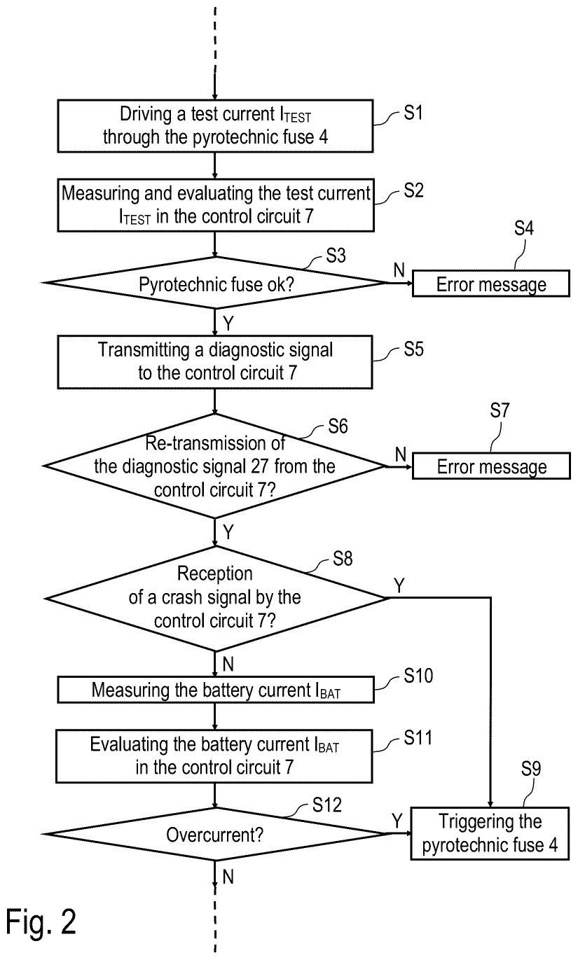

The flowchart shown in FIG. 2, which describes the operating method of the pyrotechnic battery disconnect system 1 according to the invention, is now described below.

It should be noted that the individual steps in the procedure involve testing the pyrotechnic fuse 4 (steps S1-S4), external diagnosis of the control circuit 7 (steps S5-S7), and the actual check for a malfunction and triggering of the pyrotechnic fuse 4 (steps S8-S12). It should be noted that the testing, diagnosis, checking, and triggering do not necessarily have to take place in the order shown.

In a first step S1, the test current I_{TEST} is first driven through the pyrotechnic fuse 4 in order to test it.

In a second step S2, the test current I_{TEST} is then measured and evaluated in the control circuit 7 in order to detect a possible malfunction of the pyrotechnic fuse 4.

If a malfunction of the pyrotechnic fuse 4 is detected in step S3, an error message follows in step S4.

Otherwise, in step S5, the battery management system 23 transmits the signal 24 with the low signal level 26 as a diagnostic signal to the control circuit 7.

The battery management system 23 then checks in step S6 whether the diagnostic signal 27 is retransmitted. If this is not the case, an error message follows in step S7.

Otherwise, in step S8, a check is made as to whether the crash signal 25 is received by the control circuit 7 from the battery management system 23. If this is the case, the pyrotechnic fuse 4 is triggered in step S9.

Otherwise, the battery current I_{BAT} is measured in step S10.

In the next step S11, the battery current I_{BAT} is then evaluated to detect an overcurrent situation.

If an overcurrent situation is detected in step S12, the pyrotechnic fuse is triggered in step S9.

Otherwise, the operating procedure is repeated in a loop.

The invention is not limited to the preferred embodiment described above. Rather, a variety of variants and modifications are possible which also make use of the inventive concept and therefore fall within the scope of protection. In particular, the invention also claims protection for the subject matter and features of the dependent claims independently of the claims referred to in each case and, in particular, also without the features of the main claim. The invention thus comprises various aspects of the invention, which enjoy protection independently of each other.

### LIST OF REFERENCE SIGNS

1 Pyrotechnic battery disconnect system
2 High-voltage battery
3 Vehicle electrical system cable
4 Pyrotechnic fuse
5 High-voltage section of the pyrotechnic battery disconnect system
6 Low-voltage section of the pyrotechnic battery disconnect system
7 Control circuit for triggering the pyrotechnic fuse
8 Low-resistance current measuring resistor (“shunt”) for measuring the battery current I_{BAT}
9 Measuring input of the control circuit with analog/digital converter for detecting the battery current I_{BAT}
10 Capacitor for providing the energy to trigger the pyrotechnic fuse
11 MOSFET for connecting the capacitor to the pyrotechnic fuse when the pyrotechnic fuse is triggered
12 Trigger output of the control circuit for triggering the pyrotechnic fuse
13 Measurement input of the control circuit with analog/digital converter for measuring the charging voltage
14 Charge control output of the control circuit
15 Switching element for connecting the transformer to the capacitor
16 Transformer for charging the capacitor
17 Digital test output for driving the test current I_{TEST} through the pyrotechnic fuse
18 Low-resistance current measuring resistor (“shunt”) for measuring the test current I_{TEST} through the pyrotechnic fuse
19 Diode
20 Measuring input of the control circuit with analog/digital converter for detecting the test current I_{TEST} through the pyrotechnic fuse
21 Interface connection of the control circuit with analog/digital converter for receiving the crash signal and for receiving and retransmitting the diagnostic signal
22 Potential separation element
23 Battery management system (BMS)
24 Signal to the interface connection of the control circuit
25 High signal level as trigger signal in the event of a crash
26 Low signal level as diagnostic signal
27 Diagnostic signal transmitted back to the battery management system by the control circuitry.
HV High voltage potential (HV: High voltage)
I_{PYRO} ≈2 A trigger current for triggering the pyrotechnic fuse
I_{BAT} Battery current
I_{LADE} Charging current for charging the capacitor
I_{TEST} Test current ≈100 mA for testing the pyrotechnic fuse without triggering it
LV Low voltage potential (LV: Low voltage)
U_{LADE} Charging voltage for charging the capacitor
U_{MESS} Voltage drop across the current measuring resistor for measuring the battery current
U_{V} Supply voltage for charging the capacitor

1. A pyrotechnic battery disconnect system comprising:
a) a high-voltage electric battery with a low side at low-voltage potential and a high side at high-voltage potential,
a pyrotechnic fuse for electrically disconnecting the high-voltage battery, wherein the pyrotechnic fuse is connected in series with the high-voltage battery and is arranged on the high side of the high-voltage battery so that the pyrotechnic fuse is at the high-voltage potential, and
c) a control circuit with a trigger output for triggering the pyrotechnic fuse, wherein the pyrotechnic fuse disconnects the high-voltage battery when triggered,
wherein
the control circuit is also arranged on the high side of the high-voltage battery and is at the high-voltage potential in order to prevent a brief short circuit between the high-voltage potential of the pyrotechnic fuse and the low-voltage potential when the pyrotechnic fuse is triggered.

2-22. (canceled)

23. The pyrotechnic battery disconnect system according to claim 1, further comprising:
an electrical energy storage device for providing the electrical energy for triggering the pyrotechnic fuse, and
a controllable first switching element for electrically connecting the electrical energy storage device to the pyrotechnic fuse for triggering the pyrotechnic fuse, wherein the first switching element can be controlled via the trigger output of the control circuit.

24. The pyrotechnic battery disconnect system according to claim 23, wherein
the control circuit controls the controllable first switching element for triggering the pyrotechnic fuse in such a way that the energy storage device is connected to the pyrotechnic fuse for a specific trigger duration, wherein a specific trigger current flows through the pyrotechnic fuse, and
the trigger current and the trigger duration together are sufficiently large to trigger the pyrotechnic fuse.

25. The pyrotechnic battery disconnect system according to claim 24, wherein
the trigger current is at least 500 mA, and
the trigger duration is at least 500 μs.

26. The pyrotechnic battery disconnect system according to claim 23, wherein
the electrical energy storage device comprises a capacitor,
the controllable first switching element comprises a power transistor, and
the control circuit is an integrated circuit.

27. The pyrotechnic battery disconnect system according to claim 23, wherein a current limiter is arranged between the electrical energy storage device and the pyrotechnic fuse in order to limit a trigger current to a maximum value and thereby keep the trigger current as constant as possible during a trigger duration.

28. The pyrotechnic battery disconnect system according to claim 27, wherein
the maximum value of the trigger current specified by the current limiter is no more than 5 A,
the trigger current is essentially constant between switching edges during the trigger duration and exhibits only fluctuations of less than 50%,
the current limiter has a constant current source.

29. The pyrotechnic battery disconnect system according to claim 23, wherein
a transformer is provided for charging the electrical energy storage device,
the transformer receives a supply voltage on an input side,
the transformer is connected to the energy storage device on an output side and supplies the energy storage device with a charging voltage, and
the charging voltage is greater than the supply voltage.

30. The pyrotechnic battery disconnect system according to claim 1, wherein
a first current sensor is provided which measures a battery current of the high-voltage battery,
the control circuit has a first measuring input connected to the first current sensor in order to detect the battery current, and
the control circuit triggers the pyrotechnic fuse when an evaluation of the measured battery current indicates an overcurrent condition.

31. The pyrotechnic battery disconnect system according to claim 30, wherein
the first current sensor is arranged on the high side of the high-voltage battery,
the first current sensor has a first low-resistance current measuring resistor which is connected in series with the high-voltage battery so that the battery current also flows through the first low-resistance current measuring resistor,
the control circuit measures a voltage drop across the first low-resistance current measuring resistor via the first measuring input as a measure of the battery current, and
the first low-resistance current measuring resistor has a resistance value of less than 100 mΩ.

32. The pyrotechnic battery disconnect system according to claim 1, wherein
the control circuit has a test output for testing the pyrotechnic fuse during a test procedure without triggering the pyrotechnic fuse,
during the test procedure, the control circuit drives a test current through the pyrotechnic fuse via the test output, wherein the test current is so small that it is insufficient to trigger the pyrotechnic fuse,
a second current sensor is provided to measure the test current,
the control circuit has a second measuring input which is connected to the second current sensor in order to detect the test current.

33. The pyrotechnic battery disconnect system according to claim 32, wherein
the test output of the control circuit is a digital output,
the test current is less than 1 A,
the second current sensor has a second current measuring resistor which is arranged between the test output of the control circuit and the pyrotechnic fuse and through which the test current flows during the test process, wherein the second measuring input of the control circuit measures a voltage drop across the second current measuring resistor as a measure of the test current during the test process, wherein the second measuring input of the control circuit measures a voltage drop across the second current measuring resistor as a measure of the test current,
a series resistor is connected in series with the second current measuring resistor to limit the test current,
the second current measuring resistor is low-impedance, and
the second low-resistance current measuring resistor has a resistance value of less than 100 mΩ.

34. The pyrotechnic battery disconnect system according to claim 1, wherein
the control circuit has an interface connection for receiving a crash signal for triggering the pyrotechnic fuse in the event of a crash, in particular from a battery management system that is connected to a crash sensor,
a potential separation element is connected to the interface connection of the control circuit in order to decouple the control circuit, which is at high voltage potential, from the crash signal from the low voltage section.

35. Pyrotechnic battery disconnect system according to claim 34, wherein
the interface connection of the control circuit also enables the reception of a diagnostic signal and the retransmission of the diagnostic signal,
the diagnostic signal differs from the crash signal so that the control circuit can distinguish the diagnostic signal from the crash signal and does not trigger the pyrotechnic fuse when the diagnostic signal is received.′

36. The pyrotechnic battery disconnect system according to claim 35, wherein the diagnostic signal has a different signal level or a different signal shape than the crash signal.

37. The pyrotechnic battery disconnect system according to claim 34, wherein
the potential separation element enables bidirectional data transmission and, in a first transmission channel, enables data transmission to the control circuit and, in a second transmission channel, enables data transmission from the control circuit,
the two transmission channels of the potential separation element are combined towards the control circuit and connected together with the interface connection of the control circuit,
the two transmission channels of the potential separation element run separately from each other to the outside.

38. The pyrotechnic battery disconnect system according to claim 37, wherein the data transmission in the two transmission channels is analog.

39. The pyrotechnic battery disconnect system according to claim 1, wherein
a controllable second switching element is provided for connecting a transmitter to the electrical energy storage device,
the control circuit has a charge control output which controls the second control element, and
the control circuit has a third measuring input which is connected to the energy storage device in order to measure the charging voltage at the energy storage device.

40. The pyrotechnic battery disconnect system according to claim 1, wherein
the control circuit has a first analog/digital converter at a first measuring input, which converts an analog external measured value of the electrical voltage dropping across a first low-resistance current measuring resistor into a corresponding internal digital value,
the control circuit has a second analog/digital converter at a second measuring input, which converts an analog external measured value of the electrical voltage dropping across a second current measuring resistor into a corresponding internal digital value,
the control circuit has a third analog/digital converter at a third measuring input, which converts an analog external measured value of the charging voltage into a corresponding internal digital value, and
the control circuit has a fourth analog/digital converter at an interface connection, which converts the externally incoming crash signal or the externally incoming diagnostic signal into a corresponding digital value.

41. The pyrotechnic battery disconnect system according to claim 1, wherein
the control circuit triggers the pyrotechnic fuse in the event of a crash, and
the control circuit triggers the pyrotechnic fuse in the event of an overcurrent.

42. The pyrotechnic battery disconnect system according to claim 1, wherein the following components are integrated in a common assembly:
a first current sensor for measuring a battery current,
the control circuit for triggering the pyrotechnic fuse,
an energy storage device for providing the energy for triggering the pyrotechnic fuse,
a second current sensor for measuring the test current,
a transformer for supplying the charging voltage to the energy storage device,
a potential separation element,
a first switching element for connecting the energy storage device to the pyrotechnic fuse,
a diode,
a series resistor for limiting the test current,
a current limiter for limiting the trigger current,
a second switching element for connecting the energy storage device to the transmitter, and
a microcontroller for communicating with the control circuit.

43. A motor vehicle electrical system with a pyrotechnic battery disconnect system according to claim 1.

44. A motor vehicle with a motor vehicle electrical system according to claim 43.

45. An operating method for a pyrotechnic battery disconnect system according to claim 1, said method comprising the following step:
controlling the pyrotechnic fuse with a trigger current from a control circuit to trigger the pyrotechnic fuse,
wherein the control circuit is also arranged on the high side of the high-voltage battery and is connected to the high-voltage potential in order to avoid a short-term short circuit between the high-voltage potential of the pyrotechnic fuse and the low-voltage potential when the pyrotechnic fuse is triggered.

46. The operating method according to claim 45, further comprising the following steps for diagnosing the control circuit:
transmitting a diagnostic signal from an external source to the control circuit, and
retransmitting the diagnostic signal from the control circuit to an external source, to indicate that the control circuit is functioning correctly.

47. The operating method according to claim 45, further comprising the following steps for testing the pyrotechnic fuse by the control circuit:
driving a test current through the pyrotechnic fuse from the control circuit, wherein the test current is so small that it is insufficient to trigger the pyrotechnic fuse,
measuring the test current using a second current sensor, and
evaluating the measured test current by the control circuit to assess the functionality of the pyrotechnic fuse.

48. The operating method according to claim 45, further comprising the following steps for triggering the pyrotechnic fuse:
measuring the battery current using a first current sensor,
evaluating the measured battery current in the control circuit to detect an overcurrent,
triggering the pyrotechnic fuse by the control circuit in the event of an overcurrent, and
receiving a crash signal by the control circuit and triggering the pyrotechnic fuse by the control circuit when the crash signal is received.
